(19) United States
(12) Patent Application Publication
(10) Pub. No.: US 2024/0353130 A1
(43) Pub. Date: Oct. 24, 2024

(54) VENTILATION AND AIR-CONDITIONING SYSTEM

(71) Applicant: FRAMATOME GmbH, ERLANGEN (DE)

(72) Inventors: Christof Da Silva Weber, HERZOGENAURACH (DE); Nancy Triebel, ERLANGEN (DE)

(21) Appl. No.: 18/682,429

(22) PCT Filed: Jul. 6, 2022
(86) PCT No.: PCT/EP2022/068702

§ 371 Date: Feb. 8, 2024

(30) Foreign Application Priority Data
Aug. 10, 2021 (DE) 10 2021 120 799.1

(51) Int. Cl. F24F 7/06; F24F 7/00; F24F 13/02

(52) U.S. Cl. CPC F24F 7/06; F24F 13/0218; F24F 2007/004

(57) ABSTRACT

A ventilation and air-conditioning system for a room includes a cooling air supply system, a supply air duct system and at least one enclosure. The enclosure includes an inlet, an outlet, and heat storage elements. The ventilation and air-conditioning system is configured such that when the operation of the cooling air supply system fails, a natural convection airflow occurs through the enclosure from the inlet to the outlet, the natural convection airflow being cooled by transferring heat to the heat storage elements. The supply air duct system is arranged above the inlet at a distance from the inlet. A gap is defined between the supply air duct system and the inlet. The inlet of the enclosure is adapted to be in constant flow communication with the room by air flowing from the room through the gap into the inlet of the enclosure.

### CROSS REFERENCE TO RELATED APPLICATIONS

This application is the U.S. National Phase of PCT Appl. No. PCT/EP2022/068702 filed Jul. 6, 2022, which claims priority to DE 10 2021 120 799.1, filed Aug. 10, 2021, the entire disclosures of which are incorporated by reference herein.

### TECHNICAL FIELD

The present disclosure relates to a ventilation and air-conditioning system for a room.

### BACKGROUND

Modern control components and systems, especially in nuclear power plants, generate a strong heat emission through convection and radiation into the technical room in which they are installed. That is why the cooling of such rooms has become increasingly important.

Normally, this cooling is achieved by an active ventilation and air-conditioning system that blows cooled air into the plant room. However, in the event of a failure of the active cooling function, the systems present in the room typically reach the maximum permissible temperature after only about 2 hours.

It is known, in particular from WO 2019/105559, that it is necessary to provide a passive emergency cooling mode to increase the time (hereinafter referred to as “cooling period”) during which the equipment present in the room reaches the maximum permissible temperature, for example up to 24 hours. This is achieved, for example, by providing a passive system with phase change materials that act as a heat accumulator.

However, such systems are not entirely satisfactory, especially in terms of their robustness and reliability. In fact, such systems use intermediate parts, especially for switching from active to passive cooling mode. These intermediate parts can be damaged or lose their function over a long period of time in standby, which reduces the reliability of such systems.

### SUMMARY

An aim of the present disclosure is to provide an emergency cooling mode for an active ventilation and air-conditioning system in case of failure of the active cooling function, in particular due to power failure. In particular, the current cooling period is to be extended. The system should work reliably and be easy to install and maintain.

To this end, the present disclosure proposes a ventilation and air-conditioning system.

The basic idea is passive switching from active room cooling to passive room cooling with the help of heat storage elements. There is a passive switchover from forced cooling mode, in which the heat storage elements inside the enclosure are cooled, to natural convection cooling mode, in which the previously cooled heat storage elements provide cooling capacity for the natural convection air flow. Moreover, this switching takes place without additional measures or additional components, which increases the robustness, and thus the reliability, of the system.

The present disclosure also relates to a building comprising a room, which has a heat source and a ventilation and air-conditioning system as described above.

The present disclosure is explained by means of the following description of a configuration, which refers to the attached drawings.

The individual features of the claims and the description are to be regarded as disclosed in any combination or sub-combination, provided they are not technically incompatible.

### BRIEF SUMMARY OF THE DRAWINGS

Preferential configurations of the present disclosure will now be described in detail through drawings, wherein:

FIG. 1 shows a top view of a room containing a number of electrical or electronic regulation and control components that generate heat during operation.

FIG. 2 shows a lateral sectional view of the room along the sectional line II-Il indicated in FIG. 1 in which a ventilation and air-conditioning system according to the present disclosure is installed and in which an active normal cooling mode is visualised by arrows indicating the air flow.

FIG. 3 shows the lateral sectional view of FIG. 2, in which a passive emergency cooling operation is visualised.

FIG. 4 shows a more detailed sectional view of a ventilation and air-conditioning system shown in FIG. 2 and FIG. 3.

### DETAILED DESCRIPTION

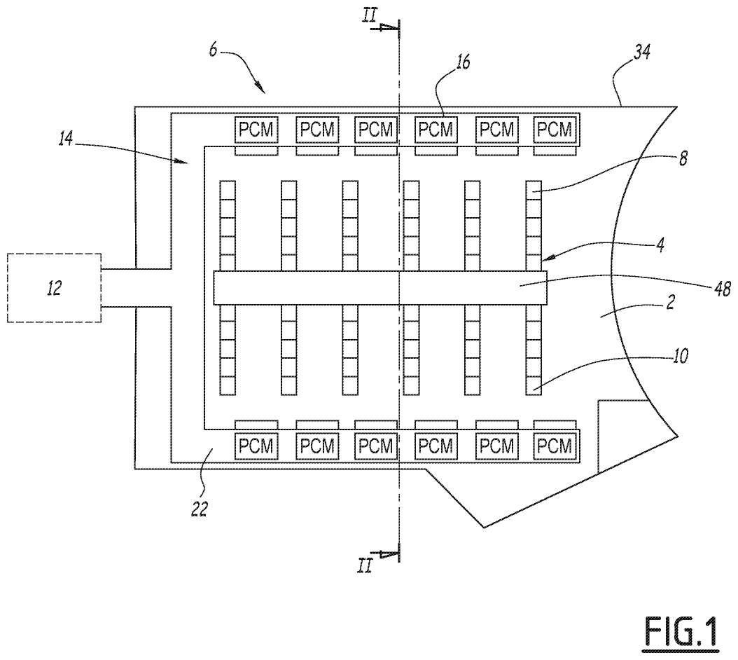

FIG. 1 shows a top view of a room 2 containing a heat source 4 and a ventilation and air-conditioning system 6.

Room 2 is in particular a technical room in a nuclear power plant.

The heat source 4 comprises several electrical and electronic components 8, in particular regulation and control components, which generate heat during operation. The regulation and control components 8 are housed in cabinets 10, for example, in a central area of the room 2.

Alternatively, the heat source 4 is of a different type than the electrical/electronic components described so far.

The ventilation and air-conditioning system 6 blows cooled air into the room 2 during operation in order to keep the room temperature below an acceptable maximum value.

The room temperature should be kept below 25° C. in continuous operation, for example.

In some configurations, heating is also integrated, resulting in a combined heating, ventilation and air-conditioning system.

The ventilation and air-conditioning system 6 comprises a cooling air supply system 12, a supply air duct system 14 connected to the cooling air supply system 12, and at least one enclosure 16 including an inlet 18 and an outlet 20.

The cooling air supply system 12 includes, for example, an air cooler provided by, for example, a vapour compression cycle refrigeration machine or thermoelectric cooling, and a fan or blower for producing a forced flow of cooled air through the supply air duct system 14.

For example, the cooling air supply system 12 produces cooled air at a temperature of between 15 and 20° C.

The cooling air supply system 12, which is only schematically indicated in FIG. 1, is arranged outside the room 2, for example.

During operation of the cooling air supply system 12, there is a forced flow of cooled air from the cooling air supply system 12 through the supply air duct system 14.

The supply air duct system 14 is configured to direct the forced flow of cooled air from the cooling air supply system 12 to the inlet 18 of the enclosure 16 during operation of the cooling air supply system 12.

In the configuration example shown in FIG. 1, the ventilation and air-conditioning system 6 comprises several enclosures 16, which are preferably arranged in parallel.

As shown in FIG. 1, the enclosures 16 are preferably arranged in a row and preferably on a wall 34 of the room 2.

By way of example, the enclosures 16 are arranged in two parallel rows on two opposite walls 34 of the room 2.

Alternatively, the enclosures 16 are arranged in the centre of the room 2 and in particular between the various components 8.

The supply air duct system 14 includes corresponding branches to each of these enclosures 16.

The supply air duct system 14 comprises at least one air duct 22.

Preferably, the air duct 22 is an air hose made of textile material. Textile material means, for example, a textile fabric, in particular a textile fabric made of polyester. Such a textile fabric made of polyester offers good resistance to environmental and chemical influences and is easy to wash or clean.

Alternatively, a metallic air duct 22 can be used.

The air duct 22 directs the forced flow of cooled air from the cooling air supply system 12 to each of the enclosures 16.

For this purpose, the air duct 22 comprises, for example, a connection for each row of enclosures 16.

Alternatively, the supply air duct system 14 comprises multiple air ducts 22, for example one air duct 22 for each row of enclosures 16.

If the air duct 22 is an air hose made of textile material, the air hose 22 preferably has a circular cross-section as shown in the figures. Such a cross-section ensures uniform air distribution. Alternatively, the air hose 22 has a semi-circular cross-section.

The air hose 22, for example, has a diameter of between 300 mm and 800 mm.

The air hose 22 is preferably permeable over the entire surface. This means that part of the forced flow of cooled air can escape at any point in the air hose 22. The supply air duct system 14 preferably includes supporting openings 24 that direct the forced flow of cooled air from the cooling air supply system 12 to the inlet 18 of a respective enclosure 16 during operation of the cooling air supply system 12.

Preferably, at least one opening 24 is arranged opposite the inlet 18 of each enclosure 16.

If the air duct 22 is an air hose made of textile material, the openings 24 are preferably formed by nozzles. These nozzles 24 are preferably located on the underside of the air hose 22. Each nozzle 24 directs a stream of cooled air towards the inlet 18 of one of the enclosures 16. These are, for example, full cone nozzles which direct a cone of cooled air at the respective inlet 18, or coneless nozzles, or opening nozzles punched into the air hose.

The nozzles 24 assist the flow by directing the forced flow of cooled air to the inlet 18 of a respective enclosure 16.

If the air duct 22 is a metallic air duct, the openings 24 can be formed by nozzles or discharge grilles. In this case, the openings 24 are preferably the only air outlets from the air duct 22 for the forced flow of cooled air.

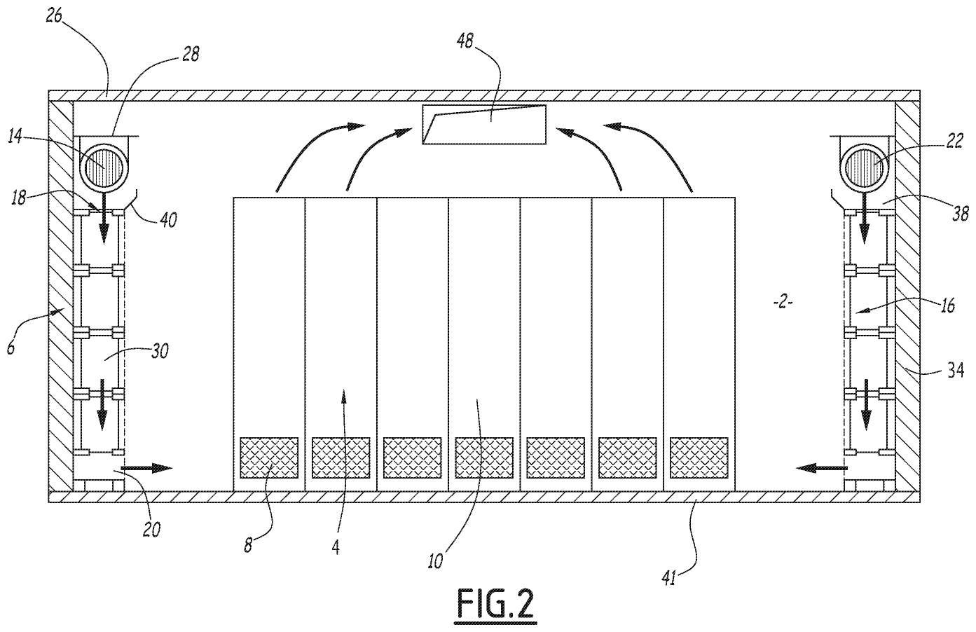

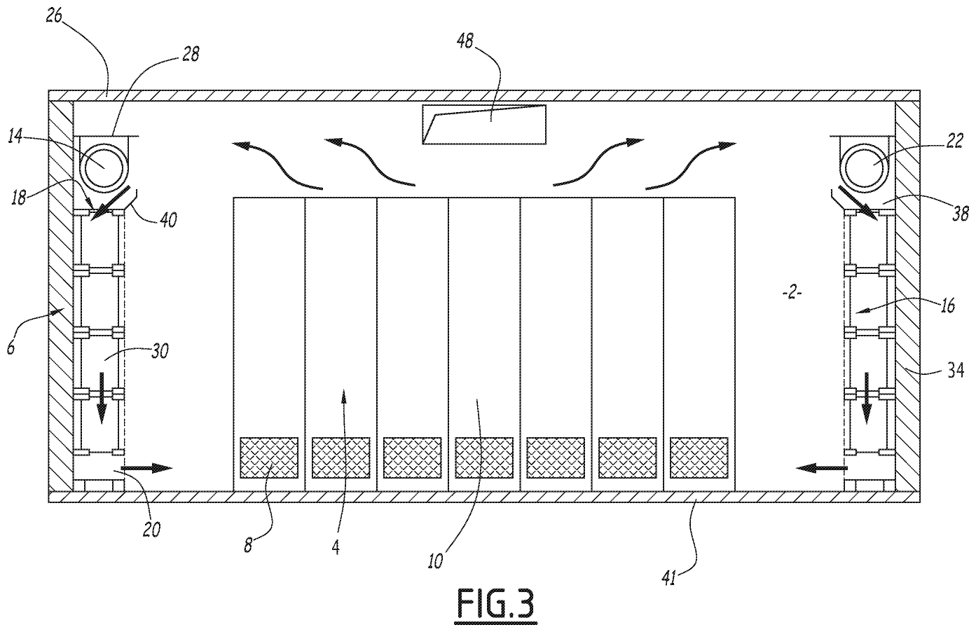

As shown in FIGS. 2 and 3, the supply air duct system 14 is advantageously arranged near a ceiling 26 of the room 2, for example at a distance of at most 20 cm from the ceiling 26.

For this purpose, the ventilation and air-conditioning system 6 comprises a support 28 for suspending the supply air duct system 14 from the ceiling 26 of the room 2.

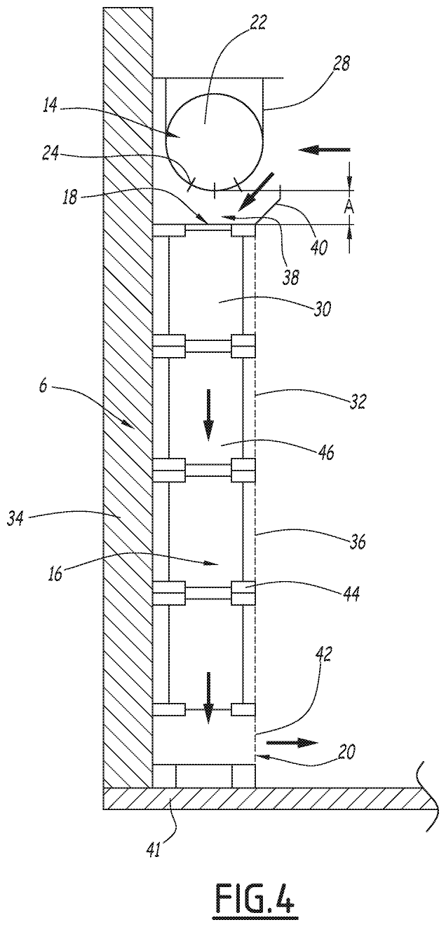

The holder 28 comprises, for example, a rope suspension, preferably a two-sided rope suspension as shown in FIG. 4. Alternatively, the bracket 28 comprises a suspension rail.

Alternatively, each enclosure 16 comprises a holder for receiving the supply air duct system 14. In this case, the supply air duct system 14 does not require a separate suspension to the ceiling 26.

Each enclosure 16 comprises heat storage elements 30, which are arranged within the enclosure 16 between the inlet 18 and the outlet 20. As each enclosure 16 is substantially identical, only one enclosure 16 is described below with reference to FIG. 4.

The enclosure 16 preferably comprises a rectilinear, vertically oriented section that directs a downward airflow during the cooling operation.

The enclosure 16 includes side walls 32 (facing the room and wall side) extending vertically between the inlet 18 and the outlet 20.

In the example shown in the figures, one of the side walls 32 is against the wall 34 of the room 2.

The enclosure 16 comprises perforated metal panels 36 forming at least one side wall 32 of the enclosure 16, and in particular forming the side wall 32 of the enclosure 16 positioned remotely from the wall 34 of the room 2.

These perforated panels 36 define access doors to the enclosure 16, for example for maintenance work.

The perforated sheet metal panels 36 are dimensioned with their hole pattern in such a way that the heat storage elements 30 in the enclosure 16 can also absorb a part of direct heat radiation in the event of failure of the active cooling air flow.

The inlet 18 is located at the upper end of the enclosure 16, in particular below the supply air duct system 14.

The supply air duct system 14 is arranged above the inlet 18 at a distance A from the latter, a gap 38 being defined between the supply air duct system 14 and the inlet 18. The distance A is measured along the vertical direction.

As a result of this gap A, the inlet 18 of the enclosure 16 is constantly in flow connection with the room 2, in that air can flow from the room 2 through the gap 38 into the inlet 18 of the enclosure 16.

The gap A should be large enough to allow sufficient air to flow from the room 2 between the inlet 18 and the air duct 22, while at the same time being small enough to ensure that little cooled air is lost from the openings 24. The distance A, for example, is between 50 mm and 250 mm.

Advantageously, as shown in FIG. 4, the enclosure 16 comprises a baffle 40 located at an upper end of the enclosure 16 to direct air from the chamber 2 into the inlet 18 of the enclosure 16. The baffle 40 is configured to direct air from an upper region of the room 2, such as warm air, to the gap 38, while preventing cooled air from flowing from the openings 24 through the gap 38 into the room 2. This means that the forced flow of cooled air from the openings 24 can flow almost completely through the inlet 18 into the enclosure 16.

Air from the room 2, in particular heated air in emergency cooling mode, is guided through the baffle 40 to the inlet 18 and then flows through the enclosure 16. This creates a reliable emergency cooling of the room 2 in a simple manner in the event of a failure of the cooling air supply system 12.

The outlet 20 leads into the room 2 and forms the exit point of the air from the enclosure 16. The outlet 20 is located near a floor 41 of the chamber 2, as shown in figures. The outlet 20 comprises, for example, a grille 42.

The enclosure 16 comprises a support structure 44 which is arranged inside the enclosure 16. The heat storage elements 30 are arranged inside the enclosure 16 by means of the support structure 44 so that, during normal operation, the forced flow of cooled air provided by the cooling air supply system 12 flows over them.

Although there is some pressure drop due to the heat storage elements 30, the remaining free space between the heat storage elements 30 and/or between the heat storage elements 30 and the side walls 32 of the enclosure 16 ensures that the airflow between the inlet 18 and the outlet 20 is not blocked.

Preferably, the heat storage elements 30 have a plate shape, in particular with flat sides oriented parallel to the main flow direction.

According to one configuration, several heat storage elements 30 are arranged in parallel and/or one behind the other with respect to the flow direction inside the enclosure 16.

The heat storage elements 30 are preferably made of a phase change material (PCM) 46.

The PCM 46 of the heat storage elements 30 is preferably selected to freeze upon contact with the forced flow of cooled air from the cooling air supply system 12, which typically has a temperature in the range of 16° C. to 30° C.

The PCM 46 is also selected to perform a phase change from solid to liquid in the temperature range of 16° C. to 30° C.

In other words, the PCM 46 preferably melts under natural convection with a melting temperature in the range of 16° C. to 30° C.

With this freezing/melting, the hysteresis must be taken into account.

The PCM 46 is preferably based on salt hydrates, as salt hydrates are non-flammable or at least hardly flammable. In addition, salt hydrates do not have a memory effect that negatively affects their heat storage capacity during multiple freezing and melting cycles. Salt hydrates also have a high volumetric latent heat storage capacity.

Alternatively, PCM 46 is based on paraffins.

The following is a description of the normal cooling operation of the ventilation and air-conditioning system 6, i.e. during operation of the cooling air supply system 12, with reference to FIG. 2.

In FIG. 2, the air flow through the enclosures 16 and through the room 2 is shown schematically by corresponding arrows.

The cooling air supply system 12 generates a forced flow of cooled air. This forced flow of cooled air is then distributed through the supply air duct system 14. The supply air duct system 14, and in particular the supporting openings 24 in the air duct 22, direct the forced flow of cooled air from the cooling air supply to the inlet 18 of the enclosure(s) 16. The forced flow of cooled air then flows through the enclosure(s) 16, thus cooling and freezing the heat storage elements 30 during normal cooling operation and preparing them for any subsequent emergency cooling operation.

In normal cooling mode, the heat storage elements 30 are constantly cooled, and can thus store cold.

Preferably, for safety reasons, the temperature before and after the heat storage elements 30 is measured in order to derive their heat storage capacity.

After flowing through the heat storage elements 30, the cooled air exits each enclosure 16 at the respective outlet 20 and is then distributed to the cabinets 10 by natural airflow in the floor. Due to the higher density of the cooled air, the airflow is maintained at a low room level, especially near the floor.

The air in the room is heated by the heat output of the components 8 and rises towards the room ceiling. The heated air is then discharged from the room 2 through an exhaust system 48 under the ceiling 26.

In normal cooling mode, therefore, the heated air is almost exclusively exhausted through the room 2 exhaust system 48 and only a negligible amount of heated air enters each enclosure 16 through the respective inlet 18.

As described above, the ventilation and air-conditioning system 6 is configured such that, during operation of the cooling air supply system 12, there is a forced flow of cooled air from the cooling air supply system 12 through the supply air duct system 14 and then through the enclosure(s) 16 from the respective inlet 18 to the respective outlet 20, thereby cooling and preferably freezing the heat storage elements 30.

There now follows a description of the emergency cooling operation of the ventilation and air-conditioning system 6, i.e. when the operation of the cooling air supply system fails, with reference to FIGS. 3 and 4.

If the cooling air supply system 12 fails, for example due to a power failure, the cooling air supply system 12 and the exhaust system 48 will not generate a forced flow of cooled air and therefore no cooled air will flow from the supply air duct system 14 into the inlet 18 of the enclosure(s) 16. In this case, the temperatures in the room 2 and between the components 8 can exceed a critical value relatively quickly.

The passive emergency cooling mode is shown schematically in FIG. 3 by arrows indicating the direction of flow.

Heated air having a temperature in the range of, for example, 24° C. to 52° C. rises to the ceiling of the room and enters the or each cooled enclosure 16 as a natural convection air flow due to the temperature difference to the cooled interior of the enclosure(s) 16, via the respective inlet 18. The heated air then flows through the enclosure(s) 16, and in particular through the heat storage elements 30, and cools down.

The switchover from forced airflow to natural airflow is thus carried out without any additional active or passive function.

During the passive cooling process, the PCM 46 of the heat storage elements 30 is heated by the flow of warm air passing through it and changes its state from solid to liquid (melting). Due to the phase change of the PCM 46 and the associated latent heat, a relatively large heat storage capacity can be achieved. The heat storage elements 30 thus act as a latent heat store and provide cooling capacity for the natural convection air flow. Thus, the temperature of the PCM 46 is kept approximately constant until complete melting.

As in normal cooling mode, the cooled air exits the or each enclosure 16 at the respective outlet 20 in the bottom area and is distributed by natural air flow to the heat generating components 8 to cool them down.

In this way, a natural convection air flow through the room 2 and through the enclosure(s) 16 is established and supported as long as the cooling capacity of the heat storage elements 30 is not exceeded.

As described above, the ventilation and air-conditioning system 6 is configured such that when the operation of the cooling air supply system 12 fails, a natural convection airflow occurs through the enclosure(s) 16 from the respective inlet 18 to the respective outlet 20, the natural convection airflow being cooled by transfer of heat to the heat storage elements 30.

If the cooling air supply system 12 is brought back into operation, for example when the electrical power is switched back on, a forced flow of cooled air through the enclosure(s) 16 is again established and the heat storage elements 30 are therefore refrozen. Switching from natural convection air flow to forced air flow also takes place without any additional active or passive function.

This ventilation and air-conditioning system 6 ensures inherently safe cooling of the room for a certain cooling period, even in the event of a power failure.

Overall, thanks to the system according to the present disclosure, a relatively long cooling period, for example of up to 24 hours of passive (emergency) cooling is achieved after the failure of the cooling air supply system 12. The exact cooling period depends in particular on the number of heat storage elements 30, the PCM 46 used and the geometry of the enclosure 16.

The inventors have performed experiments and numerical calculations with a system according to the present disclosure, the system comprising a total of twelve enclosures 16, each enclosure containing a stack of 180 salt hydrate PCM heat storage elements 30. Each heat storage element 30 had dimensions of approx. 450×300×15 mm, a weight of approx. 630 kg (incl. enclosure and base frame) and a heat capacity of approx. 83,000 kJ. These tests and calculations have confirmed that such an exemplary system can provide a total cooling capacity in the range of approx. 1,000 MJ for a room of approx. 72 m² and 3.4 m height with approx. 11.5 kW heating load for at least 24 hours.

In addition, the passive switching from forced flow to natural air flow without additional devices or measures ensures the robustness and thus the reliability of the ventilation and air-conditioning system 6.

What is claimed is:

1-14 (canceled)

15. A ventilation and air-conditioning system for a room, the room containing a heat source and the ventilation and air-conditioning system, comprising:
a cooling air supply system;
at least one enclosure;
an inlet located at an upper end of the enclosure;
an outlet configured to lead into the room; and
heat storage elements arranged within the enclosure between the inlet and the outlet; and
a supply air duct system connected to the cooling air supply system, the ventilation and air-conditioning system being configured such that:
during operation of the cooling air supply system, there is a forced flow of cooled air from the cooling air supply system through the supply air duct system and then through the enclosure from the inlet to the outlet, thereby cooling and preferably freezing the heat storage elements, and
when the operation of the cooling air supply system fails, a natural convection air flow occurs through the enclosure from the inlet to the outlet, the natural convection air flow being cooled by transfer of heat to the heat storage elements;
the supply air duct system being arranged above the inlet at a distance from the inlet, a gap being defined between the supply air duct system and the inlet,
the inlet of the enclosure being adapted to be in constant flow connection with the room by air flowing from the room through the gap into the inlet of the enclosure.

16. The ventilation and air-conditioning system according to claim 15, wherein the supply air duct system is further comprising at least one air duct.

17. The ventilation and air-conditioning system according to claim 16, wherein the air duct is an air hose made of textile material.

18. The ventilation and air-conditioning system according to claim 16, wherein the air duct is an air hose made of textile material and has a circular or semicircular cross-section.

19. The ventilation and air-conditioning system according to claim 15, wherein the supply air duct system is further comprising supporting openings which, during operation of the cooling air supply system, direct the forced flow of cooled air from the cooling air supply system to the inlet of a respective enclosure.

20. The ventilation and air-conditioning system according to claim 15, further comprising at least one bracket for suspending the supply air duct system from a ceiling of the room, or each enclosure comprises a bracket for receiving the supply air duct system.

21. The ventilation and air-conditioning system according to claim 15, wherein the enclosure is further comprising perforated metal panels forming at least one side wall of the enclosure.

22. The ventilation and air-conditioning system according to claim 15, wherein the enclosure is further comprising a baffle arranged at the upper end of the enclosure and adapted to direct the air from the room into the inlet of the enclosure.

23. The ventilation and air-conditioning system according to claim 15, wherein the heat storage elements are made of a phase change material.

24. The ventilation and air-conditioning system of claim 23, wherein the phase change material performs a phase change from solid to liquid in a temperature range of 16° C. to 30° C.

25. The ventilation and air-conditioning system according to claim 23, wherein the phase change material is based on salt hydrates.

26. The ventilation and air-conditioning system according to claim 15, wherein the heat storage elements have a plate shape.

27. A building comprising:
a room, the room comprising a heat source and the ventilation and air-conditioning system according to claim 15.

28. The building according to claim 27, wherein the outlet is located near a floor of the room.

29. The building according to claim 27, wherein the heat source comprises multiple electrical and electronic components.
